(19) United States
(12) Patent Application Publication
(10) Pub. No.: US 2024/0190277 A1
(43) Pub. Date: Jun. 13, 2024

(54) A Wireless Charging Assembly for an Electric Vehicle

(71) Applicant: WiTricity Corporation, Watertown, MA (US)

(72) Inventors: Daniel Smith, Hallam (AU); Antonio Rocco, Hallam (AU)

(73) Assignee: WiTricity Corporation, Watertown, MA (US)

(21) Appl. No.: 18/554,363

(22) PCT Filed: Apr. 8, 2022
(86) PCT No.: PCT/AU2022/050314

§ 371 Date: Oct. 6, 2023

(30) Foreign Application Priority Data
Apr. 8, 2021 (AU) 2021901026

(51) Int. Cl. B60L 53/302; B60L 53/124; H02J 50/00; H02J 50/10; H05K 7/20

(52) U.S. Cl. CPC B60L 53/302; B60L 53/124; H02J 50/005; H02J 50/10; H05K 7/20145

(57) ABSTRACT

A wireless charging assembly for an electric vehicle, including a control unit, a charging pad for mounting to a floor and spaced from the control unit and a conduit extending between the control unit and the charging pad. The conduit has a first internal passageway for delivery of cooling air from an airflow generator to the charging pad for cooling the charging pad and a second internal passageway for return of cooling air from the charging pad back to the airflow generator. The first and second internal passageways and the charging pad forming a substantially closed circuit that is closed to atmosphere to prevent ingress of external matter into the first and second internal passageways and the charging pad. The conduit has a third internal passageway for accommodating one or more cables extending from the control unit to the charging pad. The interior of the third internal passageway being accessible through a wall of the third internal passageway for inserting the one or more cables into the third internal passageway.

### TECHNICAL FIELD

The present invention relates to a wireless charging assembly for an electric vehicle.

The reference to “wireless” above is a reference to the charging that occurs between the charging assembly of the invention and a vehicle, which is wireless charging. That is, there is no wired connection between the charging assembly and the vehicle for the charging to take place. Also, the vehicles intended to be wirelessly charged include any electric vehicles including cars, busses, trucks, and autonomous electric vehicles, as well as hybrid vehicles that include a combination of internal combustion engine and electric motor or motors. The charging that takes place is of the electric storage of the vehicle, which principally at present is the battery of the vehicle.

### BACKGROUND OF INVENTION

The discussion of the background to the invention that follows is intended to facilitate an understanding of the invention. However, it should be appreciated that the discussion is not an acknowledgement or admission that any aspect of the discussion was part of the common general knowledge as at the priority date of the application.

Electric vehicles are becoming more popular and the number of electric vehicle manufacturers is increasing. Most of the major vehicle manufacturers are now offering electric vehicle options or planning to offer electric vehicle options in the relatively near future.

Electric vehicles require charging similar to petrol and diesel vehicles requiring refilling. The frequency of charging is dependent on the frequency of use of the vehicle and the distances driven. While at an early stage, many countries that are promoting use of electric vehicles are establishing networks of electric vehicle charging stations so that charging can take place during travel from one place to the next. However, even the fastest charging still takes over an hour and so is an inconvenience to undertake during driving such as during a long drive.

Most owners of electric vehicles prefer to charge their vehicles when they are parked and they can leave the vehicle for the required charging time. For many owners of electric vehicles, this means charging their vehicles overnight in their own garage or carport. Home charging stations have typically included a wall connector and a flexible cable that has a suitable plug at the free end thereof for connecting with the electric vehicle. The cable can be supplied at any length suitable for connecting with vehicle and cables of between 2.5 to 8 m are normal. In use, the vehicle driver drives the vehicle into a position proximal to the wall connector where the cable can reach the vehicle and then the cable is plugged into the charging point of the vehicle to commence charging.

Cable chargers of the above kind are effective, but they present inconveniences in that the cable that extends to the vehicle can obstruct passage past the vehicle and can also present a tripping hazard. Moreover, the cable must be unwound from a wall support for use and then re-wound onto the wall support after use. This can be tedious particularly if the vehicle is used several times during the day and each time the cable must be connected and disconnected.

Wireless vehicle chargers provide an alternative to the cable form of charging discussed above. Such chargers charge by induction by creating a magnetic-resonance field between a charging pad located on a floor surface of a garage or carpark for example, and a charge receiving device on the underside of the vehicle. Advantageously, all that is required is for the vehicle to be driven to locate the charge receiving device over the charging pad and then charging can commence automatically by the charging system sensing the proximity of the charge receiving device to the charging pad, or by the system being operated manually.

In either of the cable chargers or the wireless chargers, significant current is delivered to the vehicle and this can generate significant heat in the charging system that needs to be removed for charging to continue. Accordingly, in each form of charger, cooling systems have been developed and these have employed circulating liquid or air as the cooling medium. For wireless chargers, some have employed fans within the charging pad to generate a cooling airflow. While the airflow is sufficient for the air cooling to be effective, a downside is that air is drawn into the charging pad for circulation within the charging pad and is then discharged from the charging pad. Ingress and egress of air is through openings in the wall structure of the charging pad which advantageously simplifies the cooling structure, but disadvantageously means that the air intake is adjacent the floor on which the charging pad is located and thus debris such as dirt, dust and moisture can be entrained in the air that enters the charging pad. To prevent this, filters can be employed but these require periodic replacement or cleaning to ensure adequate cooling, while failure to replace or clean the filters can lead to premature failure of the charging pad.

In addition, the ingress of debris into the charging pad does not only occur through entrainment in air entering the air intake. Rather, debris can enter the charging pad through either of the air intake or exhaust in ambient conditions simply by the intake and exhaust openings being at floor level and by the normal displacement of debris within the room (usually a garage) by wind, such as might occur when the garage doors are opened, or as might be generated by movement of bodies within the room, e.g. by a vehicle entering the or leaving the garage. Again, filters can be employed to prevent entry of debris, but require periodic maintenance for proper operation of the charging pad.

The present invention has been developed to provide an alternative to the present wireless vehicle chargers, in particular to provide a different structure for cooling the charging pad of such chargers.

### SUMMARY OF THE INVENTION

According to the present invention there is provided a wireless charging assembly for an electric vehicle, including:
a control unit,
a charging pad for mounting to a floor and spaced from the control unit
a conduit extending between the control unit and the charging pad,
the conduit having a first internal passageway for delivery of cooling air from an airflow generator to the charging pad for cooling the charging pad and a second internal passageway for return of cooling air from the charging pad back to the airflow generator, the first and second internal passageways and the charging pad forming a substantially closed circuit that is closed to atmosphere to prevent ingress of external matter into the first and second internal passageways and the charging pad,
the conduit having a third internal passageway for accommodating one or more cables extending from the control unit to the charging pad, the interior of the third internal passageway being accessible through a wall of the third internal passageway for inserting the one or more cables into the third internal passageway.

A wireless charging assembly according to the present invention advantageously forms a substantially closed circuit for cooling air to circulate so that there is no requirement for an air intake or an air exhaust to be formed in the charging pad. The absence of an air intake and an air exhaust means that charging pad can be substantially fully closed to the surroundings so that foreign matter and other debris that might otherwise enter the charging pad has no openings through which entry to the charging pad is available. Not only can dirt, dust and moisture be prevented from entering the charging pad, insect ingress and infestation is also advantageously prevented. The closed circuit may not be completely or fully closed against any ingress of foreign matter and other debris, but the intention is that the closed circuit be as close to completely or fully closed as possible. Minor leakage within the closed circuit can be tolerated while still preventing most of the potential ingress of foreign matter and other debris into the closed circuit.

The floor to which the charging pad is mounted is any floor that a car can be parked on or over and that a charging pad can be mounted to. The floor can be an inside or outside floor, for example within a garage or under a carport. The floor can be a floor of a commercial carpark for example, which could be an outdoors carpark or a partially outdoors carpark in which the carpark has a roof or multiple levels that form roofs over lower levels, but which do not have walls and therefore are open to the weather. The floor could be concreted or asphalted for example, or it could be a natural earth floor, such as dirt or gravel floor.

The charging pad can be mounting to the surface of the floor, or it can be mounted within the floor, such as within a recess within the floor. An upper surface of the charging pad can be flush with the floor surface, or it can sit proud of the floor surface or below the floor surface.

The control unit can also be mounted to the floor in or on which the charging pad is mounted. Alternatively, the control unit can be elevated above the floor and can be mounted on a wall, or it can be elevated on a stand and be free standing. It can be mounted on a pedestal or within a cabinet for example and in each case it can be spaced from the wall. The control unit could be part of a booth or box that is fixed to a floor. This is likely to be adopted in commercial carparks for example, where one control unit might control multiple charging pads. In commercial carparks, use of a charging pad might attract a fee and thus the control unit could be part of a booth or box that already exists for payment of parking fees.

The conduit can be formed as a wall box for mounting on a wall and can include a first conduit portion for extending from the control unit downwardly and a second conduit portion for extending along the floor to the charging pad. The first conduit portion can extend downwardly from the control unit along the wall. If the control unit is spaced from the wall, such as being mounted on a pedestal or within a cabinet, the first conduit portion could extend downwardly from the control unit along the pedestal or within the cabinet.

The control unit will typically house or support operational components of the wireless charging assembly, such as power conditioning hardware, including a power factor controller, auxiliary power supplies, control circuits, a heat exchanger, and a display for displaying operational parameters such as charging status and parking position. The control unit can additionally house or support electrical apparatus for connection to the utility electricity supply, including for example filters, circuit breakers, surge protection devices, etc. The control unit can be a box within which the operational components are housed, or it can be a panel or board on which the operational components are supported, or a combination or both. Some of the operational components may not require easy accessibility and so may be contained securely within the control unit, whereas other operational components, display components for example, may be permanently in sight and easily accessible.

The cables that extend from the control unit to the charging pad can carry power and/or data. Thus, the control unit can be connected to mains power and deliver power to the charging pad through the cables in the conduit. The cables can also transmit data to and from the control unit to the charging pad for various purposes, such as for initiating charging by sensing a vehicle, commands to alter the charge value as charging progresses, monitoring the available power and selecting charging timing to maximise charging efficiency. The control unit may operate differently if the power source is a solar source as compared to a traditional fossil fuel power source, so that charging would be timed to happen during the day and possibly during times when the solar power being generated is excess to the other power needs of the dwelling or building the solar power is associated with. The control unit can be arranged to operate with particular parameters suitable to the place of installation of the wireless charging assembly of the present invention.

The charging pad will house the relevant induction facility and the housing of the charging pad can be fully enclosed to eliminate entry points for debris to enter the interior of the housing. The charging pad can have a suitable connection interface for connection with the conduit, although in some forms of the invention, the conduit will be integrally connected to the charging pad housing, or at least a section of conduit will be integrally connected to the charging pad housing, with the section being connectable to another section or sections of conduit that extend to the control unit.

Mounting of the charging pad to the floor can utilise bolts, screws or adhesive, or the charging pad can simply be placed on the floor without additional fixing. In this latter arrangement, the conduit may provide some locating load to retain the charging pad in place while the weight of the charging pad may also assist it to remain in one place.

The conduit can take any suitable form and where the conduit extends along the floor between the control unit and the charging pad, the conduit is preferably is formed to have a width which is greater than its height, or in other words, to be wide rather than high in order to reduce upward extension of the conduit away from the floor it extends along to reduce the likelihood of the conduit presenting a tripping hazard. A conduit of this form is also less likely to shift if engaged by the wheels of a vehicle (a motorbike in particular) or if stepped on or ridden over by a bicycle. The width can be in the order of about three times the height at the highest point of the conduit.

Like the charging pad, the conduit can extend within the floor rather than over the top of it. The conduit can thus extend within a recess formed in the floor or it can be embedded in the floor, such as a concrete floor that is poured about the conduit. The conduit can also be buried or sub terranean. Where the conduit includes a first conduit portion that extends from the control unit downwardly along a wall, the first conduit portion can extend within the wall so as to be concealed from view.

The conduit has three internal passageways. The first and second internal passageways are for the passage of cooling air while the third is for accommodating cables. It is to be noted that the cooling air can be any suitable fluid for transporting heat, although it is not expected that the cooling air will include refrigeration fluids that undergo a phase change.

The first and second internal passageways can be formed by channels or elongate compartments within the conduit that extend from the airflow generator to the charging pad. The conduit can thus include elongate internal walls that form separated passageways for flow of cooling air between the airflow generator and the charging pad. The separated passageways can be adjacent each other so that the first and second internal passageways can be on either side of an elongate wall.

In the above forms of the invention, the conduit can be thought of as having a single internal passageway that is divided into separate channels or elongate compartments to form the first, second and third internal passageways.

The third internal passageway can be adjacent the first and second internal passageways or can be between the first and second internal passageways. Alternatively, the internal passageways can be stacked so that one of the passageways is above or below the other passageways. A triangular conduit may for example, have one passageway positioned above two other passageways.

The first and second internal passageways of the conduit can be formed by the construction of the conduit as described above, or alternatively, the first and second internal passageways can be formed by tubes or hoses housed within the conduit and through which the air can flow between the airflow generator and the charging pad. Thus, in this form of the conduit, the conduit can define a single internal passageway that accommodates first and second tubes or hoses and air flows through the tubes or hoses to and from the charging pad. The third internal passageway for the cables can be formed by the interior of the single internal passageway that is not taken up by the first and second tubes or hoses, or the third internal passageway can be a separate internal passageway for accommodating cables. Alternatively, the third internal passageway can be a further tube or hose that extends through the single internal passageway of the conduit.

The third internal passageway for accommodating cables can have an opening along its length or in other words, be open along its length for the insertion of the cables into the passageway, so that the cables to not need to be threaded through the passageway from one end to the other. This is particularly advantageous where the conduit is of significant length. Thus, the third internal passageway can have an elongate slit, slot or groove to allow insertion of the cables into the passageway and while that might allow the entry of debris into the third internal passageway, the cables can be sealed at the point of entry into the control unit and the charging pad so that debris cannot enter the control unit and the charging pad via the third internal passageway.

The opening of the third internal passageway can be formed by flexible sections of a wall of the passageway that can be pushed apart for insertion of the cable. The flexible sections can be formed in a base or bottom wall of the third internal passageway for example. The flexible sections can have a resting position in which they define a slit, slot or groove between them, or in the resting position, proximal edges of the flexible sections may abut or overlap in contact between them, to close any gap between them. This latter arrangement will reduce the likelihood of debris entering the third internal passageway. In some forms of the invention, the proximal edges of the flexible sections can interlock, such as by a cooperating dovetail engagement between the proximal edges.

For insertion of the cables into the third internal passageway, the flexible sections can be displaced from the resting position to open a gap between them to facilitate pushing or insertion of the cables into the passageway. The flexible sections can resiliently return to the resting position once the cables have been inserted into the third internal passageway. Where there is an interlock between the proximal edges of the flexible sections in the resting position, the cable insertion process may require manipulation of the flexible sections beyond resilient return for the interlock to be made or re-mated. Re-mating may require a special tool to join the proximal edges together and such a tool may act like a zip closure to progressively close the proximal edges together.

The cables can be inserted into the third internal passageway progressively along the length of the passageway from one end of the conduit to the other, so that the flexible sections are likewise displaced progressively from the resting position and return to the resting position as the cables enter the passageway.

In other forms of the invention, the cables can be threaded or pushed through the conduit from one end to the other, thus removing the requirement for an opening to be formed along the length of the third internal passageway for the insertion of the cables.

As indicated above, the charging pad can have a suitable connection interface for connection with the conduit and likewise, the control unit can also have a suitable connection interface for connection with the conduit. This allows the control unit and the charging pad to be installed first and then the conduit to be connected between them. The conduit can be formed so that it can be easily cut to length to properly extend to each of the control unit and the charging pad. In other forms of the invention, the conduit can be installed first and the control unit and charging pad connected to each end of the conduit.

The conduit connection interface of the control unit and the charging pad can connect the control unit and the charging pad for air flow between them. This facilitates location or accommodation of the airflow generator in one of the control unit or the charging pad. In testing conducted to date, the length of conduit that extends from the control unit to the charging pad is sufficient to allow the cooling air that travels about the closed circuit to discard or shed the heat that it absorbs from within the charging pad so that the cooling air can return to the charging pad to extract further heat from the charging pad. In testing conducted to date, the length of conduit between the control unit and the charging pad is in the order of about 5 m. Of course, the amount of heat that can be discarded or shed from the cooling air as it travels about the closed circuit can be affected by 1) the ambient temperature and the existence of airflow within the installation site (usually a garage) within which the wireless charging assembly is located, 2) the velocity or volumetric flow rate and volume of the cooling air within the closed circuit, 3) the existence of further heat inputs that add heat to the cooling air as it travels about the closed circuit, and 4) the level of conducted heat, radiated heat and convective cooling that is available through the structure of the conduit.

In testing conducted to date, the cross-sectional area of the first and second internal passageways has been found to be optimal at about 800 mm² for a conduit length of between 3 m and 5 m. With that cross-sectional area, the resistance to air movement can be overcome by airflow generators that are low power and inexpensive. However, the cross-sectional area of the first and second internal passageways could alternatively be about 500 mm² to 1000 mm² depending on the length of the conduit.

In respect of convective cooling through the conduit, the conduit can be constructed to maximise the cooling effect by any one or more of a) suitable selection of the material of the conduit, b) increasing the cross-sectional area of the first and second internal passageways, c) decreasing the wall thickness of the first and second internal passageways, d) by forming the surface of the conduit with cooling fins or protrusions and e) by connection between the conduit and the floor, such as by adhering the conduit to the floor, such as by double sided tape or adhesive to increase heat sinking into the floor.

The control unit can be constructed for extracting heat from the cooling air. In some forms of the invention, the control unit is formed as a box or container and a double finned heatsink can be formed within the control unit whereby fins on the inside of the control unit are formed or constructed for interaction with high velocity air flow and the fins on the outside are optimised for natural convection or for forced low flow rate cooling. Heat is thus extracted from the cooling air by transfer of heat between the inside and outside fins by conduction. The fin arrangement can be formed as a solid metallic heatsink or the fins can be assisted by closed liquid/vapor phase change arrangements

The wireless charging assembly of the invention can include a cooling unit for cooling the heated cooling air that is exhausted from the charging pad. The cooling unit might employ thermoelectric cooling for example, or thermoacoustic cooling using sound waves at the resonant frequency of the conduit to transport heat from the charging pad to a cooling heat sink. The cooling unit can be located at a point in the closed circuit which is remote from the charging pad. The cooling unit could be located at the or in the control unit for example.

The conduit can extend between the control unit and the charging pad in any suitable manner. Where the conduit includes a first conduit portion for extending from the control unit downwardly and a second conduit portion for extending along the floor to the charging pad, to reduce the likelihood of the conduit becoming a tripping hazard or being an unwanted obstruction, the first conduit portion of the conduit preferably extends along the wall on which the control unit is installed, downwardly to the floor on which the charging pad is installed, and the second conduit portion extends from the wall, along the floor to the charging pad. This downward extension can be vertical, or can include lateral extension. For example, the first conduit portion may extend at an angle from the control box that is other than vertical. For the second conduit portion to extend from the wall, the conduit can include a redirector such as an elbow that redirects the conduit from a generally vertical first conduit portion to a generally horizontal second conduit portion. The elbow can extend through approximately 90°. The elbow allows the conduit to translate through a 90° bend which might not be possible by just bending the conduit where it meets the floor.

The elbow can have generally the same cross-section as the first and second conduit portions, so that the elbow can include first and second internal passageways for airflow, and a third internal passageway for accommodating cables. The elbow can be a friction connection with the first and second conduit portions, such as by the elbow and the first and second conduit portions having cooperating male and female connectors. The connection between the elbow and the first and second conduit portions should be a sealed connection to prevent the ingress of debris into the conduit through the connection.

The wireless charging assembly according to the invention can also employ a horizontal elbow for re-routing the conduit as required. For example, the conduit may extend downwardly to the floor and then across the floor and then require to be turned 90° to connect to the charging pad.

The conduit may also include elbows that turn at angles that are greater than or less than 90° so that other conduit configurations or layouts can be adopted as required.

The provision in the conduit of the third internal passageway for accommodating cables advantageously protects the cables from damage, such as from abrasion by being walked on or driven over, by car, motorbike or bicycle. Moreover, the cables can be prevented from lateral cable roll that can occur if the cable is driven over by a motorbike or bicycle and that can be dangerous to the rider of the motorbike or bicycle and damaging to the cable. The conduit can be made to be relatively flat and heavy to resist movement of the conduit along the floor on which the charging pad is mounted. The conduit can be fixed to the floor by fasteners, such as bolts, screws or adhesive.

The first and second conduit portions can be an extruded sections, extruded from rubber such as synthetic rubber. EPDM rubber can be employed, as can other rubbers such as silicone. Alternatively, hard plastics can be employed. The redirectors or elbows can be formed from injection moulded glass filled nylon or similar for example.

### BRIEF DESCRIPTION OF THE DRAWINGS

In order that the invention may be more fully understood, some embodiments will now be described with reference to the figures in which:

FIG. 1 is a layout view showing a wireless charging assembly according to one embodiment of the invention.

FIG. 2 is a cross-sectional perspective of a conduit of the wireless charging assembly of FIG. 1.

FIGS. 3 and 4 show vertical and horizontal elbows for use in a conduit of a wireless charging assembly according to the invention.

FIGS. 5 and 6 show alternative layouts views of wireless charging assemblies according to the invention.

FIG. 7 illustrates a portion of the conduit of the earlier figures in cross-section showing portions of the airflow passageways and the full cable passageway.

FIGS. 8 to 10 show different configurations of the bottom wall of the cable passageway of FIG. 7.

### DETAILED DESCRIPTION

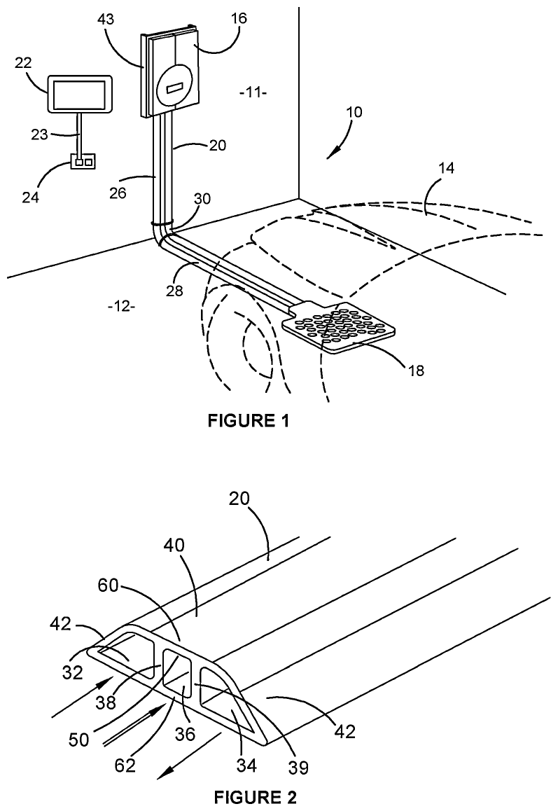

FIG. 1 is a layout view showing a wireless charging assembly 10, shown installed in a room that most likely is a vehicle or car garage. The room includes a front wall 11 and a floor 12. The wall 11 is generally at right angles to the floor 12.

The front end of a car 14 is shown in broken outline so that components of the charging assembly 10 that extend to beneath the car 14, are visible.

The charging assembly 10 includes a control unit in the form of a wall box 16 and a charging pad 18. The wall box 16 is just one form of control unit as will be apparent from the detailed discussion above. The wall box 16 is formed as an enclosure or housing to house various operational components as described earlier herein. A conduit 20 extends between the wall box 16 and the charging pad 18.

The conduit 20 houses one or more cables that extend between the wall box 16 and the charging pad 18 and the cables are operable to carry electrical services, usually comprising power and/or data. The conduit 20 is also employed to allow recirculation of cooling air between the charging pad 18 and wall box 16 as will be described later herein.

The wall box 16 is fixed to the wall 11 at a height of about 1.4 m. As discussed earlier herein, the wall box 16 can alternatively be a control unit that is mounted away from the wall 11, such as on a pedestal or within a cabinet, where wall mounting is not possible or convenient, or it can be mounted on the floor 12. Adjacent to the wall box 16 and also mounted on the wall 11, is a display 22, which can display various data associated with operation of the charging assembly 10. That data can include charging status, vehicle positioning for optimal wireless charging power, fault status amongst other things. The display 22 includes a cable or lead 23 that extends to a power socket 24 for powering the display 22. The display 22 communicates with the wall box 16 wirelessly for transfer of data.

The conduit 20 includes a first conduit portion 26 which can otherwise be called a “riser duct”, and a second conduit portion 28 which can otherwise be called a “floor duct”. As shown in FIG. 1, the first conduit portion 26 extends generally vertically and along the surface of the front wall 11. The conduit portion 26 can be fixed to the wall 11, or it can just rest against the wall 11. The conduit portion 26 can be extend into the wall 11 to be concealed within the wall 11. The second conduit portion 28 extends generally horizontally and along the floor surface 12. Again, the second conduit portion 28 can be fixed to the floor 12, or it can just rest on the floor 12, or it can be accommodated within a recess or channel within the floor 12 or it can be embedded within the floor 12. The connection of the conduit 20 to the wall box 16 and to the charging pad 18 will locate the conduit 20 against some lateral movement, while the conduit is intended to be of a weight that will provide some resistance to the movement of the second conduit portion 28 laterally relative to the floor 12.

The first conduit portion 26 extends downwardly from the wall box 16, and connects to the second conduit portion 28 via a redirector in the form of a curved elbow 30. The second conduit portion 28 extends from the elbow 30 and into connection with the charging pad 18. Cables housed in the conduit 20 thus extend between the wall box 16 and the charging pad 18.

The assembly 10 would be connected to a mains electricity supply, although such a connection is not shown in FIG. 1. In some forms of the invention, the wall box 16 would be directly connected to the mains power supply through a rear side of the wall box 16 or via a cable that extends from the wall box 16 to an electrical wall socket. In alternative arrangements, a mains connection is made within the floor 12 directly to the charging pad 18.

As explained earlier herein, the charging pad 18 will generate heat and in most cases, that heat will be sufficient to require cooling. The charging pad 18 of the present invention is expected to generate heat levels of less than 1 kW and so air cooling is appropriate. It is to be noted that in some other charging arrangements, particularly cable chargers that physically connect to the electric vehicle rather than charging wirelessly, larger amounts of heat are generated and can require the use of liquid as a coolant. The present invention thus provides advantages by the use of cooling air over the more complex arrangements required for liquid coolant.

The charging assembly 10 thus includes facility for air cooling of the charging pad 18 and to generate airflow, either of the wall box 16 or the charging pad 18 includes an internal airflow generator (that it is not visible in the figures), such as a blower or fan. The blower or fan can be relatively simple and is typically required to generate airflow of approximately 5 to 15 litres per second. Sanyo Denki America Inc provide blowers that are suitable for use in the present invention. The airflow generator can alternatively be connected into the conduit 20 intermediate the wall box 16 and the charging pad 18, but this requires separate connections and a separate housing for the airflow generator.

As described earlier herein, some prior art charging assemblies include a fan or blower within the charging pad and draw air into the charging pad through an inlet and discharge air out of the charging pad through an outlet, both of which form part of the charging pad. As can be seen in FIG. 1, the charging pad 18 is positioned directly onto the floor 12 and so is very close to any dust, dirt or moisture that might settle on the floor 12. Operation of a fan or blower within the charging pad 18 might thus entrain such dust, dirt or moisture into the charging pad, potentially affecting the operation and reliability of the charging pad. Again, as earlier described herein, filters can be employed to prevent ingress of dust, dirt and moisture, but these require periodic replacement or cleaning which presents an inconvenience to users of a charging assembly. Moreover, even when the fan or blower is not operating, both of the inlet and outlet can present entry points for insects and infestation.

Accordingly, the wireless charging assembly 10 of FIG. 1 is formed as a substantially closed circuit, such that there is no inlet or outlet openings in the charging pad 18. This prevents ingress of the dust, dirt and moisture described above, and also eliminates the entry point for insects and thus the potential for infestation. In order to create this substantially closed circuit, airflow is generated through the conduit 20 so that air can circulate between the wall box 16 and the charging pad 18 and via that circulation, the air that is exhausted from the charging pad 18 can cool as it travels back to the wall box 16 and returns to the charging pad 18.

FIG. 2 is a cross-sectional perspective view taken through the conduit 20. Each of the first and second conduit portions 26 and 28 have the same cross-section shown in FIG. 2 and so the position where the cross-section of FIG. 2 is taken is not important, other than the cross-section is not taken through the elbow 30.

The conduit 20 includes a first internal passageway 32, a second internal passageway 34 and a third internal passageway 36. Each of the first and second internal passageways 32 and 34 are for the flow of cooling air within the conduit 20. One of the passageways 32 and 34 provides a passage for flow of air from the wall box 16 and to the charging panel 18, while the other of those passageways provides a passageway for return flow of air from the charging pad 18 back to the wall box 16. The first and second internal passageways 32 and 34 thus form an airflow loop, whereby the airflow changes direction at each of the wall box 16 and the charging pad 18.

The internal passageway 36 is provided to accommodate the electrical and/or data cables that are required to extend between the wall box 16 and the charging pad 18. While the passageway 36 is shown positioned between the passageways 32 and 34, this is just one layout that is appropriate for the present invention. Alternative layouts would have the passageways 32 and 34 adjacent and separated by the wall 38, or instead of the conduit 20 having a flat or truncated top surface 40, the passageway 36 could be positioned above two adjacent passageways 32 and 34, to create a generally triangular conduit cross-section.

A benefit however of the passageway layout shown in FIG. 2, is that the conduit 20 is relatively wide and has a relatively short height above the floor 12. This minimises the likelihood of the conduit 20 forming a tripping hazard and the sloping side walls 42 provide a ramp surface that minimises resistance to the conduit being driven over at shallow lateral approach angles, such as by a motorbike or bicycle. The trapezoidal cross-sectional shape of the conduit 20 is therefore considered to be advantageous.

The trapezoidal shape of the conduit 20 is also advantageous in maximising the internal areas of the passageways 32 and 34, for increasing or maximising the convective heat loss as air travels through the passageways 32 and 34. It can be seen in FIG. 2, that the cross-sectional area of the internal passageways 32 and 34 is much greater than that of the square shaped passageway 36, so that the velocity of air through the passageways 32 and 34 can be reduced or slowed for improved convective heat loss and the sloping side walls 42 lengthen the surface area of the passageways 32 and 34 and present these as outer surfaces of the conduit 20 for improved conductive heat loss. In contrast, the passageway 36 has less external surfaces given that the walls 38 and 39 are internal within the conduit 20 and the square cross-section of the passageway 36 means the surface area of the passageway 36 is less than the surface area of the passageways 32 and 34. This of course is acceptable for the passageway 36 given it's role as a passageway for cables rather than for cooling air.

Shedding of heat from the cooling air can be by natural convection through the conduit 20, or a cooling unit can be provided and housed in either of the wall box 16 or the charging pad 18 or both. In FIG. 1, the wall box 16 has a finned heatsink 43 along the side edge of the wall box 16 which comprises fins on the inside of the wall box 16 that connect with fins on the outside. Heat is thus extracted from the cooling air by transfer of heat between the inside and outside fins by conduction.

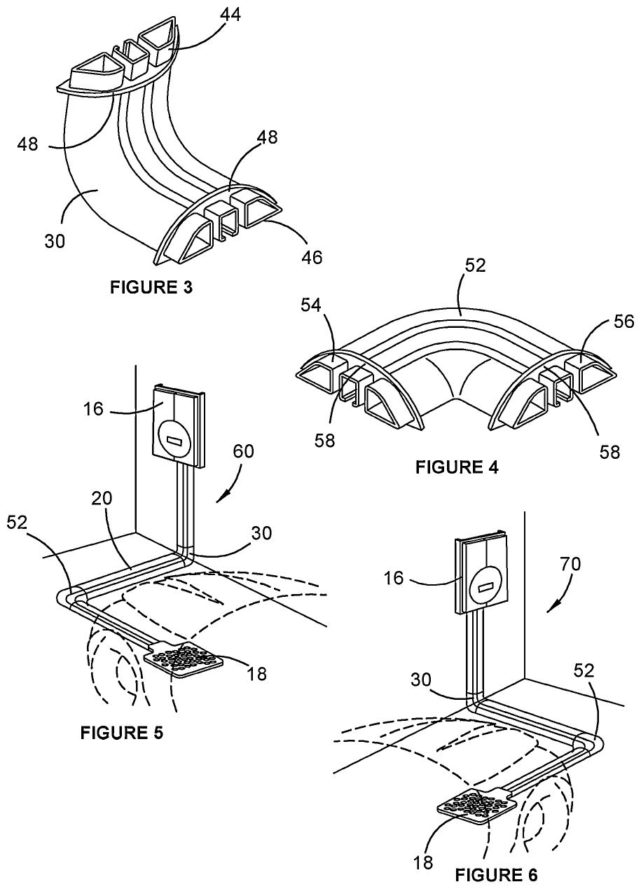

The vertical elbow 30 is shown in isolation in FIG. 3 and this shows male interfaces 44 and 46 at each end of the elbow 30, the cross-section of both of which is intended to be a friction fit into the internal passageways 32, 34 and 36 of the conduit 20. A flange 48 forms an abutment surface for end faces 50 (see FIG. 2) of the conduit 20. Thus, the elbow 30 is connectable to the first and second conduit portions 26 and 28 by push fit, although a more permanent connection can be made by the addition of adhesive glue between the cooperating connection parts, or by fixing the parts together with an external hose clamp which is pre-formed to the shape of the conduit.

The use of the elbow 30 advantageously facilitates positioning of the first conduit portion 26 against the wall 11 and the second conduit portion 26 along the floor 12 for substantially their full length. It is very unlikely that the conduit 20 could be bent through 90 degrees to achieve the same installation as shown in FIG. 1.

A horizontal elbow 52 is shown in FIG. 4 and this includes similar male interfaces 54 and 56, and similar flanges 58 to those interfaces and flanges 44, 46 and 48 of the elbow 30 and these are provided in the elbow 52 and so that conduit portions can connect to the elbow 52 in the same manner that they connect to the elbow 30. FIGS. 5 and 6 each show charging assemblies 60 and 70 that include both a vertical elbow 30 and a horizontal elbow 52. The assemblies 60 and 70 of FIGS. 5 and 6 respectively show how the charging assembly of the invention can be modified in layout to suit the positioning of the wall box 16 and the charging pad 18 for different layouts.

Not shown in any of the figures is that the second conduit portion 26 can also extend at an angle to vertical, or it can extend horizontally. The elbows 30 and 52 can be used to create various different conduit paths as may be required and additional elbows that accommodate different conduit angles can be employed.

The cable passageway 36 is formed of an external top wall 60, the internal side walls 38 and 39 and an external bottom wall 62. For insertion of cables into the passageway 36, the cables can be fed from one end of the cable through to the other, but this may not be appropriate in all circumstances, particularly where the conduit is of substantial length. Accordingly, in some forms of the invention, the bottom wall 62 is formed with an elongate opening in the form of an elongate slit, slot or groove whereby the cables can be inserted into the passageway 36 through the elongate opening. The elongate opening can have a smaller width than the diameter of the cables so that once the cables are inserted into the passageway 36, they do not easily exit the passageway 36. Also, for similar reasons to the passageways 32 and 34, it is preferred that the passageway 36 be resistant to ingress of debris and insects. Accordingly, if the conduit 20 is formed from a material that has flexibility, then the bottom wall 62 can be formed in two overlapping or mating parts that can be pushed apart for insertion of cables and which will recover resiliently once the pushing load is removed. The parts will then return to a mating position which is resistant to ingress of debris and insects.

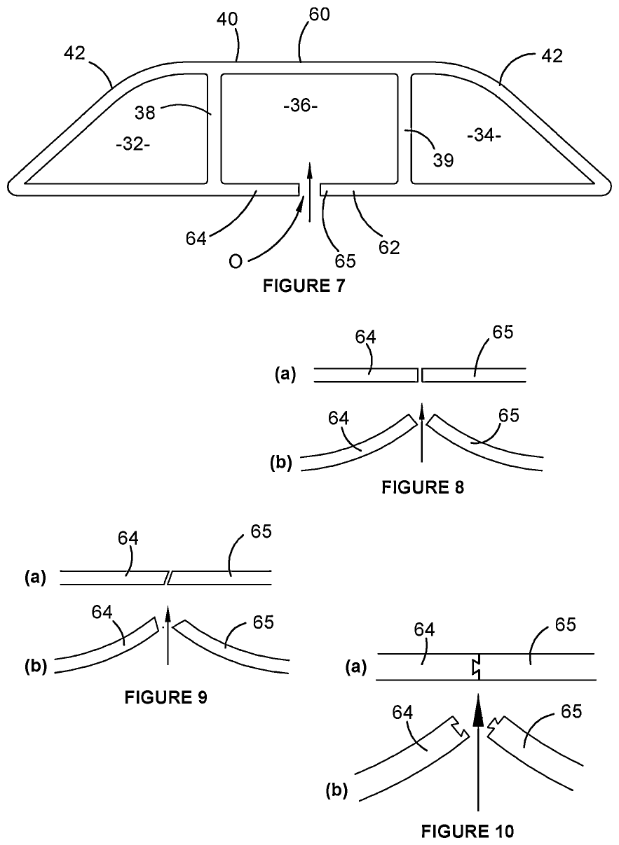

FIG. 7 illustrates a portion of the conduit 20 in cross-section showing portions of the passageways 32 and 34 and the full passageway 36. The bottom wall 62 of the passageway 36 is shown as being formed in two separated sections 64 and 65. The separated sections 64 and 65 form an opening O through which cables can be inserted into the passageway 36. The cables typically will have diameters that are greater than the width of the opening O between the sections 64 and 65, so that for insertion of the cables into the passageway 36, the sections 64 and 65 must flex inwardly. The sections 64 and 65 will recover resiliently once the cables have entered the passageway 36 back to the resting or initial position shown in FIG. 7.

FIG. 8 shows just the sections 64 and 65 of the bottom wall 62 but in FIG. 8, the proximal or facing ends or edges of the sections 64 and 65 are intended to be in very close facing relationship, or in touching or bearing engagement in the resting position. FIG. 8(a) shows that resting position.

FIG. 8(b) shows the sections 64 and 65 having been pushed inwardly to open a gap between the facing ends of the sections 64 and 65, for insertion of cables into the passageway 36.

FIG. 9 shows an alternative arrangement of the sections 64 and 65 in which the facing ends of the sections 64 and 65 are inclined for a more secure mating relationship in the resting position (FIG. 9(a)). FIG. 9(b) shows the sections 64 and 65 having been pushed inwardly to open a gap between the facing ends of the sections 64 and 65, for insertion of cables into the passageway 36.

FIG. 10 shows an alternative arrangement of the sections 64 and 65 in which there is an interlock between the facing ends of the sections 64 and 65 by forming the facing ends for a dovetail connection in the resting position as shown in FIG. 10(a). FIG. 10(b) shows the sections 64 and 65 having been pushed inwardly to detach the dovetail connection and to open a gap between the facing ends of the sections 64 and 65, for insertion of cables into the passageway 36. Return of the sections 64 and 65 to the interlocked resting position may require manipulation of the sections 64 and 65 beyond simple resilient return for the interlock to be made or re-mated. As indicated earlier herein, re-mating may require a special tool to join the facing edges together and such a tool may act like a zip closure to progressively close the facing edges together.

The wireless charging assembly 10 of the figures advantageously creates a closed circuit assembly that eliminates the possibility of ingress of foreign matter and debris into the cooling air circuit and thus importantly, eliminates the possibility of ingress of foreign matter and debris into the charging pad. This is expected to improve the operation and reliability of the charging pad and the overall wireless charging assembly. The wireless charging assembly 10 of the figures also provides a conduit structure that enables the conduit to hug the wall and/or floor, thus minimising the likelihood of the conduit 20 forming a tripping hazard and minimising the likelihood of the conduit 20 undergoing lateral movement when engaged by bicycle or motorbike wheels.

Where any or all of the terms “comprise”, “comprises”, “comprised” or “comprising” are used in this specification (including the claims) they are to be interpreted as specifying the presence of the stated features, integers, steps or components, but not precluding the presence of one or more other features, integers, steps or components.

Those skilled in the art will appreciate that the invention described herein is susceptible to variations and modifications other than those specifically described. It is understood that the invention includes all such variations and modifications which fall within the spirit and scope of the present invention.

1. A wireless charging assembly for an electric vehicle, including:
a control unit,
a charging pad for mounting to a floor and spaced from the control unit; and
a conduit extending between the control unit and the charging pad,
the conduit having a first internal passageway for delivery of cooling air from an airflow generator to the charging pad for cooling the charging pad and a second internal passageway for return of cooling air from the charging pad back to the airflow generator, the first and second internal passageways and the charging pad forming a substantially closed circuit that is closed to atmosphere to prevent ingress of external matter into the first and second internal passageways and the charging pad,
the conduit having a third internal passageway for accommodating one or more cables extending from the control unit to the charging pad, an interior of the third internal passageway being accessible through a wall of the third internal passageway for inserting the one or more cables into the third internal passageway.

2. A wireless charging assembly according to claim 1, wherein the control unit is formed as a container that houses operational components of the wireless charging assembly.

3. A wireless charging assembly according to claim 1, wherein the charging pad houses an induction facility.

4. A wireless charging assembly according to claim 1, wherein each of the control unit and the charging pad have a connection interface for connection with the conduit.

5. A wireless charging assembly according to claim 1, wherein the conduit has a width greater than its height.

6. A wireless charging assembly according to claim 5, wherein the conduit has a width that is in an order of about three times the height at the highest point of the conduit.

7. A wireless charging assembly according to claim 1, wherein the first and second internal passageways are formed as channels within the conduit by the conduit including elongate internal walls that form separated channel passageways for flow of cooling air between the airflow generator and the charging pad.

8. A wireless charging assembly according to claim 7, wherein the separated channel passageways are adjacent to each other so that the first and second internal passageways are on either side of an elongate internal wall.

9. A wireless charging assembly according to claim 1, wherein the third internal passageway is positioned between the first and second internal passageways.

10. A wireless charging assembly according to claim 1, wherein the third internal passageway is positioned adjacent to the first and second internal passageways.

11. A wireless charging assembly according to claim 1, wherein the internal passageways are configured be stacked so that one of the internal passageways is above or below the other internal passageways.

12. A wireless charging assembly according to claim 11, wherein the conduit is formed in a triangular shape in which one internal passageway is positioned above two other internal passageways.

13. A wireless charging assembly according to claim 1, wherein the first and second internal passageways of the conduit are formed by tubes or hoses housed within the conduit and through which air can flow between the airflow generator and the charging pad.

14. A wireless charging assembly according to claim 13, wherein the conduit defines a single internal passageway that accommodates first and second tubes or hoses configured to enable air to flow between the airflow generator and the charging pad, and wherein the third internal passageway defines an interior of the single internal passageway that is not taken up by the first and second tubes or hoses.

15. A wireless charging assembly according to claim 13, wherein the conduit defines:
a first internal passageway that accommodates first and second tubes or hoses configured to enable air to flow between the airflow generator and the charging pad; and
a second internal passageway for accommodating cables.

16. A wireless charging assembly according to claim 1, wherein the third internal passageway has having an opening along its length for insertion of cables into the third internal passageway.

17. A wireless charging assembly according to claim 16, wherein the third internal passageway has an elongate slit, slot, or groove along its length to allow insertion of the cables into the third internal passageway.

18. A wireless charging assembly according to claim 16, wherein the opening of the third internal passageway is formed by flexible sections of a wall of the third internal passageway that can be pushed apart for insertion of the cable.

19. A wireless charging assembly according to claim 18, wherein the wall of the third internal passageway in which the flexible sections are formed is a bottom wall of the third internal passageway.

20. A wireless charging assembly according to claim 18, wherein the flexible sections have a resting position in which they define a slit, slot, or groove between them.

21. A wireless charging assembly according to claim 18, wherein the flexible sections have a resting position in which proximal edges of the flexible sections abut or overlap in contact to close one or more gaps between them.

22. A wireless charging assembly according to claim 18, wherein the flexible sections have a resting position in which proximal edges of the flexible sections interlock.

23. A wireless charging assembly according to claim 22, wherein the proximal edges of the flexible sections interlock by a cooperating dovetail engagement between the proximal edges.

24. A wireless charging assembly according to claim 18, wherein the flexible sections are resiliently displaceable from a resting position to open a gap between the flexible sections to facilitate insertion of the cables into the passageway and to resiliently return to the resting position once the cables have been inserted into the third internal passageway.

25. A wireless charging assembly according to claim 1, wherein the cables are sealed at a point of entry into the control unit and the charging pad to prevent debris entering the control unit and the charging pad via the third internal passageway.

26. A wireless charging assembly according to claim 1, wherein the conduit is formed from rubber, synthetic rubber, EPDM rubber, or silicone.

27. A wireless charging assembly according to claim 1, wherein a cross-sectional area of the first and second internal passageways is about 800 mm² for a conduit length of between 3 m and 5 m.

28. A wireless charging assembly according to claim 1, wherein a volumetric flow rate of the cooling air within the closed circuit is about 5 to 15 litres per second.

29. A wireless charging assembly according to claim 1, wherein the airflow generator is an electrically actuated fan or blower.

30. A wireless charging assembly according to claim 1, wherein a first conduit portion of the conduit extends along a surface on which the control unit is installed, downwardly to the floor on which the charging pad is installed, and a second conduit portion extends from the surface, along the floor to the charging pad.

31. A wireless charging assembly according to claim 30, wherein the conduit includes a redirector that redirects the conduit from a generally vertical first conduit portion to a generally horizontal second conduit portion.

32. A wireless charging assembly according to claim 31, wherein the redirector has generally a same cross-section as the first and second conduit portions, so that the redirector includes first and second internal passageways for airflow and a third internal passageway for accommodating cables.

33. A wireless charging assembly according to claim 1, wherein the control unit is mounted to the floor and the conduit extends along the floor to the charging pad.

34. A wireless charging assembly according to claim 1, wherein the control unit is mounted to a surface at floor level and the conduit extends along the floor to the charging pad.

35. A wireless charging assembly according to claim 1, wherein the control unit is elevated above the floor and the conduit extends downwardly to the floor and then along the floor to the charging pad.

36. A wireless charging assembly according to claim 1, wherein the conduit extends to the charging pad within the floor.
